(19) United States
(12) Patent Application Publication
(10) Pub. No.: US 2013/0153918 A1
(43) Pub. Date: Jun. 20, 2013

(54) REO-Si TEMPLATE WITH INTEGRATED REO LAYERS FOR LIGHT EMISSION

(71) Applicants: Andrew Clark, Los Altos, CA (US); Michael Lebby, Apache Junction, AZ (US)

(72) Inventors: Andrew Clark, Los Altos, CA (US); Michael Lebby, Apache Junction, AZ (US)

(21) Appl. No.: 13/328,194

(22) Filed: Dec. 16, 2011

(51) Int. Cl. H01L 33/50; H01L 33/32

(52) U.S. Cl. 257/76; 257/98; 438/29; 257/E33.025; 257/E33.023; 257/E33.061

(57) ABSTRACT

A III-N on silicon LED constructed to emit light in the visible range includes a layer of single crystal III-N with a light emitting diode formed therein and designed to emit light at a first wavelength through a lower surface, a REO-Si template mated to the layer of single crystal III-N and designed to approximately crystal lattice match a silicon substrate, and a light emission layer of rare earth oxide selected to receive and absorb light at the first wavelength, up-convert the absorbed light, and re-emit light at a second wavelength in the visible range. The lower surface of the REO-Si template is either mated to the upper surface of a crystalline silicon substrate with the light emission layer integrated into the REO-Si template or mated to an upper surface of the light emission layer with a lower surface of the light emission layer mated to the crystalline silicon substrate.

### FIELD OF THE INVENTION

This invention relates in general to the use of rare earth oxides for the up-conversion of UV light from LEDs to visible light.

### BACKGROUND OF THE INVENTION

It has been found that III-N nitrides are a desirable semiconductor material in many electronic and photonic applications. Specifically, many III-N materials can be used to fabricate light emitting devices or diodes (LEDs) for commercial uses. One problem is that light emitted from standard III-N LEDs (e.g. GaN) is in the UV range and is not visible. Also, it is most convenient to fabricate the III-N LEDs on a silicon substrate so that they can be easily manufactured using standard semiconductor techniques and facilities and so that they can be integrated into or with other silicon semiconductor devices and structures.

As understood in the art, the III-N nitride semiconductor material must be provided as a crystalline or single crystal formation for the most efficient and useful bases for the fabrication of various electronic and photonic devices therein. Further, the single crystal III-N nitride semiconductor material is most conveniently formed on single crystal silicon wafers because of the extensive background and technology developed in the silicon semiconductor industry. However, because of differences in the crystal lattice structure it is extremely difficult to grow single crystal III-N nitrides on silicon wafers.

It would be highly advantageous, therefore, to remedy the foregoing and other deficiencies inherent in the prior art.

Accordingly, it is an object of the present invention to provide new and improved light emitting devices including REO-Si templates with integrated REO layers for light emission.

It is another object of the present invention to provide new and improved III-N on silicon light emitting devices that emit light in the visible range.

It is another object of the present invention to provide new and improved methods of fabricating III-N on silicon light emitting devices that emit light in the visible range.

### SUMMARY OF THE INVENTION

Briefly, to achieve the desired objects and aspects of the instant invention in accordance with a preferred embodiment thereof, provided is a III-N on silicon LED constructed to emit light in the visible range including a layer of single crystal III-N with a light emitting diode formed therein and designed to emit light at a first wavelength through a lower surface, a REO-Si template mated to the layer of single crystal III-N and designed to approximately crystal lattice match a silicon substrate, and a light emission layer of rare earth oxide selected to receive and absorb light at the first wavelength, up-convert the absorbed light, and re-emit light at a second wavelength in the visible range. The lower surface of the REO-Si template is either mated to the upper surface of a crystalline silicon substrate with the light emission layer integrated into the REO-Si template or mated to an upper surface of the light emission layer with a lower surface of the light emission layer mated to the crystalline silicon substrate.

The desired objects and aspects of the instant invention are further realized in accordance with a specific method of fabricating a III-N on silicon light emitting diode constructed to emit light in the visible range. The method includes the steps of (not necessarily in the order listed) providing a crystalline silicon substrate having an upper surface and a lower surface, epitaxially growing a layer of single crystal III-N nitride with a light emitting diode formed therein and designed to emit light at a first wavelength through a lower surface, epitaxially growing a REO-Si template with an upper surface mated to the lower surface of the layer of single crystal III-N nitride and a lower surface designed to approximately crystal lattice match the upper surface of the silicon substrate, epitaxially growing a light emission layer of rare earth oxide selected to receive and absorb light at the first wavelength, up-convert the absorbed light, and re-emit light at a second wavelength in the visible range, and mating the lower surface of the REO-Si template to one of the upper surface of the crystalline silicon substrate with the light emission layer integrated into the REO-Si template or to an upper surface of the light emission layer with a lower surface of the light emission layer mated to the crystalline silicon substrate.

The desired objects and aspects of the instant invention are further realized in accordance with a method of fabricating a III-N on silicon light emitting diode constructed to emit light in the visible range. The method including the steps of providing a crystalline silicon substrate having an upper surface and a lower surface, epitaxially growing a light emission layer of single crystal rare earth oxide on the upper surface of the crystalline silicon substrate, and selecting the light emission layer to receive and absorb light at a first wavelength, up-convert the absorbed light, and re-emit light at a second wavelength in the visible range, epitaxially growing a REO-Si template on the light emission layer with a lower surface mated to an upper surface of the light emission layer, and epitaxially growing a layer of single crystal III-N nitride on an upper surface of the REO-Si template, designing the layer of single crystal III-N nitride to emit light at the first wavelength through a lower surface, and forming a light emitting diode in/on the layer of single crystal III-N nitride.

### BRIEF DESCRIPTION OF THE DRAWING

The foregoing and further and more specific objects and advantages of the instant invention will become readily apparent to those skilled in the art from the following detailed description of a preferred embodiment thereof taken in conjunction with the drawings, in which:

FIG. 1 is a simplified layer diagram of a stress engineered epitaxial wafer;

FIG. 2 is a simplified layer diagram of a stress engineered epitaxial template with integrated REO layers for single wavelength light emission in accordance with the present invention; and

FIG. 3 is a simplified layer diagram of a stress engineered epitaxial template with integrated REO layers for multiple wavelength light emission in accordance with the present invention.

### DETAILED DESCRIPTION OF THE DRAWINGS

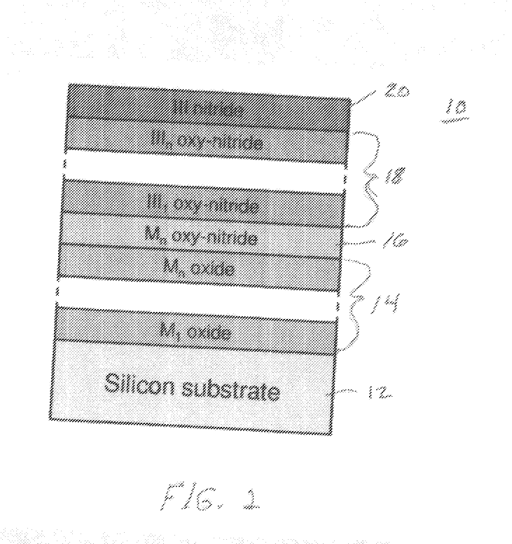

Referring to FIG. 1, a simplified layer diagram is illustrated of one embodiment of a REO-Si template 10 designed to buffer or facilitate the growth of III-N nitride on silicon. In this example template 10 is formed or grown directly on a single crystal silicon substrate 12. A rare earth oxide (REO) structure 14 is grown directly on the surface of substrate 12. Rare earth oxide structure 14 may be considered a plurality of single crystal or crystalline layers or a single layer of single crystal or crystalline material with a plurality of sub-layers, either of which will be referred to herein for convenience of understanding as a “plurality of layers”. Further, rare earth oxide structure 14 may vary from the bottom to the top and/or within each layer either linearly or in a step by step process. It should be understood that throughout this disclosure when directional terms such as “upper”, “lower”, “top” and “bottom” are used they indicate a direction when the device being discussed is viewed in the accompanying figures and are not intended to in any way limit the scope of the invention.

Rare earth oxide structure 14 is specifically designed or engineered to gradually adjust from the crystal lattice of substrate 12 to approximately the crystal lattice of rare earth oxy-nitride layer 16, also designated Mₙ oxy-nitride. This gradual adjustment of the crystal lattice between the interface with substrate 12 and the interface with layer 16 is generally designed to closely or approximately match the lattice spacing between adjacent layers or to provide a predetermined amount of stress or mismatch in lattice spacing. For example, layer 16 can be unstressed or stressed, either compressive or tensile, depending on the selection or engineering of the rare earth composition in structure 14. That is, structure 14 is selected or engineered such that it constrains the overgrown rare earth oxy-nitride layer 16 to a predetermined stress state, either unstressed, or compressive, or tensile. The gradual adjustment of the crystal lattice spacing performed in the growth of structure 14 is defined herein as stress engineering.

In this specific example, structure 14 varies or changes from M₁ oxide to Mₙ oxide, with ‘n’ representing 2, 3, etc. Generally, M, the rare earth in each layer (step or gradation), may change or may be a mix or alloy of different rare earths to change the lattice spacing the desired amount. Thus, it can be seen that through stress engineering of structure 14 any desired amount of stress, tensile or compressive, can be provided in the rare earth oxy-nitride layer 16 while still retaining a single crystal or crystalline material.

In some applications it may be desirable to use a rare earth in layer 16 that more closely lattice matches the lattice and lattice spacing of a III oxy-nitride structure 18 grown on layer 16. As described above in relation to structure 14, structure 18 may be considered a plurality of single crystal or crystalline layers or a single layer of single crystal or crystalline material with a plurality of sub-layers, either of which will be referred to herein for convenience of understanding as a “plurality of layers”. In this embodiment, structure 18 includes a plurality of layers changing from III₁ oxy-nitride to IIIₙ oxy-nitride. Further, III oxy-nitride structure 18 may vary from the bottom to the top and/or within each layer either linearly or in a step by step process.

In III oxy-nitride structure 18, an oxy-nitride is defined as a mix of oxygen and nitrogen according to the formulas OₓN₍₁₋ₓ₎ where 0<x<1. Preferably, the III material in structure 18 remains the same but x varies between zero and 1 as the structure is grown from layer 16 to a final layer 20 of single crystal or crystalline III nitride. It should be noted that layer 20 can be conveniently grown by a continuation of the same process that produces structure 18 by simply allowing x to go to zero. However, the III material can vary from the lower layer of structure 18 (i.e. the III₁ oxy-nitride) abutting layer 16 to the upper layer (i.e. the IIIₙ oxy-nitride) abutting layer 20.

One major purpose of the varying structure 18 is to provide an interface or chemical engineering between Mₙ oxy-nitride layer 16 and layer 20 of III nitride. That is, through chemical engineering the crystal lattice of Mₙ oxy-nitride layer 16 is gradually matched to the crystal lattice of III nitride layer 20 while retaining the stress specifically engineered into Mₙ oxy-nitride layer 16. The stress is specifically engineered to prevent or overcome any bowing or other deformities or cracking in III nitride layer 20.

In this specific example, structure 14, layer 16 and structure 18 form REO-Si template 10 and provide a crystalline formation that is stress and chemical engineered to match, or facilitate the growth of a III-N material on a silicon substrate. A complete description of a REO-Si template can be found in a copending United States patent application entitled “Rare Earth Oxy-Nitride Buffered III-N on Silicon”, bearing Ser. No. 13/196,919, filed 3 Aug. 2011, and incorporated herein by reference. It will be understood that REO-Si template 10 is simply one example used to explain the operation of a REO-Si template and other embodiments may be provided that perform basically the same or similar functions. Thus, through the use or incorporation of a REO-Si template a layer of single crystal III nitride can be conveniently grown with a much larger diameter and with virtually any desired thickness.

Thus, the problem of fabricating a III-N LED on a silicon substrate is alleviated by the use or incorporation of a REO-Si template. However, as explained briefly above, a III-N LED fabricated on a REO-Si template will emit light in the UV range, which has limited value. It is therefore desirable to use generally the REO-Si template to fabricate an LED that is capable of emitting light in the visible range. Throughout this disclosure the term “mate” or “mated” is used to indicate that one element, such as the REO-Si template, is grown directly on and approximately crystal matched with a second element, such as the single crystal silicon substrate.

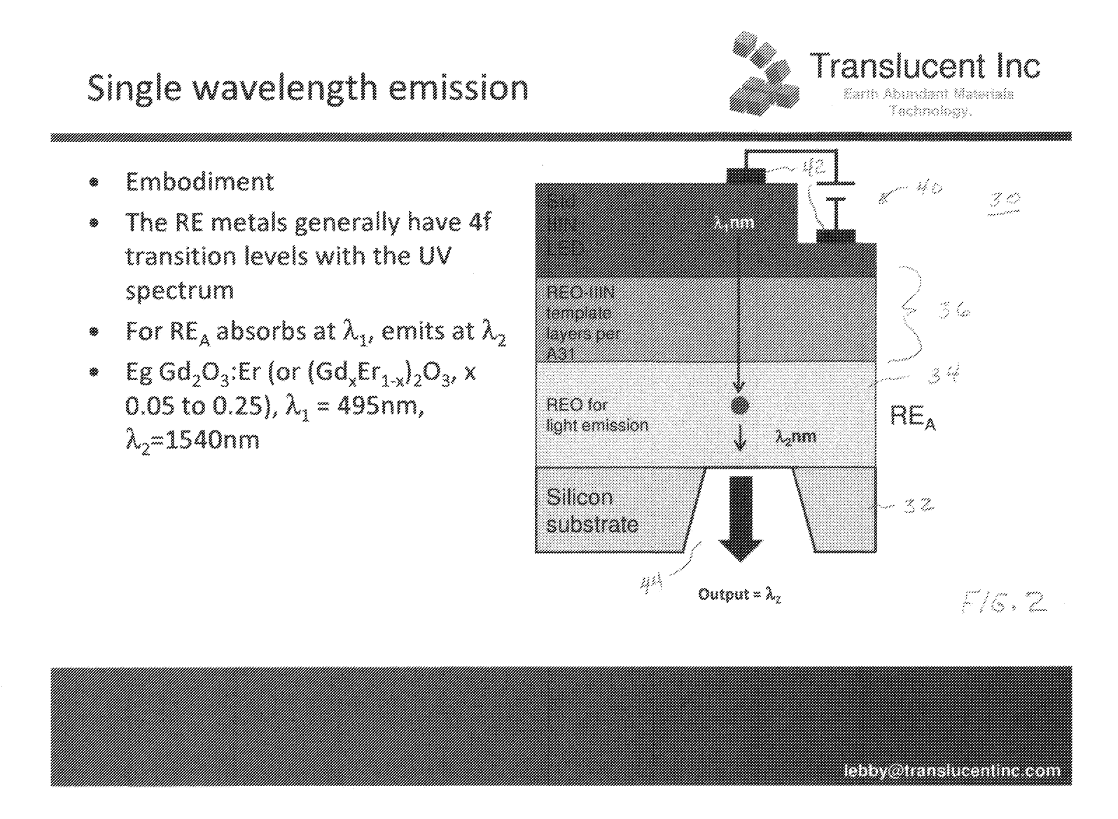

Turning to FIG. 2, a visible light emitting diode 30 incorporating a REO-Si template with integrated REO light emission layers in accordance with the present invention is illustrated. As will be understood, visible light emitting diode 30 is designed for single wavelength light emission. Visible light emitting diode 30 includes a single crystal silicon substrate 32, a single crystal rare earth oxide light emission layer 34, a REO-Si template 36 generally as described above in conjunction with FIG. 1, and a single crystal III-N LED 40. Throughout this disclosure whenever rare earth materials are mentioned it will be understood that “rare earth” materials are generally defined as any of the lanthanides as well as scandium and yttrium or combinations thereof. Also, the III materials described herein can be any of the materials or combinations of the materials in the group III metals of the periodic table, including aluminum (Al), gallium (Ga), etc.

Single crystal silicon substrate 32, it will be understood, is or may be a standard well know single crystal silicon wafer or portion thereof generally known and used in the semiconductor industry. Single crystal silicon substrate 32 is not limited to any specific crystal orientation but could include <111> silicon, <110> silicon, <100> silicon or any other orientation or variation known and used in the art. Also, while silicon substrate 32 is illustrated as single crystal pure silicon it should be understood that single crystal substrates composed of materials containing elements other than silicon or in addition to silicon may be used and all such substrates will be referred to generically as “silicon” substrates herein.

Single crystal rare earth oxide light emission layer 34 is grown on silicon substrate 32 using any of the well known growth methods, such as MBE, MOCVD, PLD (pulsed laser deposition), sputtering, ALD (atomic layer deposition), or any other known growth method for thin films. Further, the growth method used will generally be used for all additional layers and may conveniently be employed to grow the entire structure in a continuous process sometimes referred to herein as performed within a one wafer single epitaxial process.

Light emission layer 34 is specifically selected to up-convert emissions received from III-N LED 40 to visible light. As understood in the art, spectral conversion materials have been developed that absorb energy emitted at one wavelength and reemit it in a different spectral range or a different wavelength. Most of these spectral conversion materials provide “up-conversion” phenomena, which is the absorption of higher spectral range energy and the reemission at a lower spectral range. Thus, up-conversion materials absorb spectral energy above 1200 nm (generally around 1500 nm) and reemit it at, for example, 400 nm to 800 nm (visible light).

In a typical example, III-N LED 40 emits at a wavelength of λ₁ equal to 1540 nm, which is in the UV range and invisible to the human eye. Light emission layer 34 includes for example Gd₂O₃:Er or (GdₓEr₁₋ₓ)₂O₃, where x is in a range of 0.05 to 0.25. Because of up-conversion in layer 34, the emissions from LED 40 at λ₁ will be absorbed and layer 34 will emit at a wavelength λ₂, which in this specific example is 495 nm or within the visible spectrum. The various rare earth metals generally have 4f transition levels with the UV spectrum. Thus, to convert UV emission from III-N LED 40 to visible light a rare earth metal oxide is selected with a transition level that corresponds to the emission from III-N LED 40.

While the rare earth oxide (REO) incorporated into layer 34 is selected for its optical properties, the REO layers in template 36 are selected for their physical or lattice matching properties. Generally, the rare earth oxide (REO) incorporated into layer 34 will be a ternary alloy (RE₁₋ₓ RE^{A}ₓ)₂O₃, where the second RE(A, B, etc.) has the requisite optical transitions. In the above example (GdₓEr₁₋ₓ)₂O₃), Gd₂O₃ has a lattice spacing of 10.81 Å compared to 2a_{Si} with a lattice spacing of 10.86 Å, or approximately two times the lattice spacing of silicon. Er₂O₃ has a lattice spacing of 10.55 Å, (Gd₁₋ₓErₓ)₂O₃ has a lattice spacing between 10.55 Å and 10.81 Å, depending upon the ratio of Gd and Er in the material. With this in mind, it should be understood that layer 34 can actually be integrated into template 36 as one or more of the REO physical matching layers and may not, in fact, be a separate layer.

With light emission layer 34 completed, either as a separate layer or layers or integrated into template 36 as one or more layers of template 36, template 36 is completed and III-N LED 40 is grown on the upper surface. As will be understood from the above explanation, the III-N materials in III-N LED 40 are selected to emit at a wavelength that corresponds with the up-conversion materials included in light emission layer 34. III-N LED 40 is formed by fabricating contacts 42 on the surface of the single crystal III-N layer. In this embodiment an opening 44 is formed in the lower or backside surface of substrate 32 for the output emission from light emission layer 34.

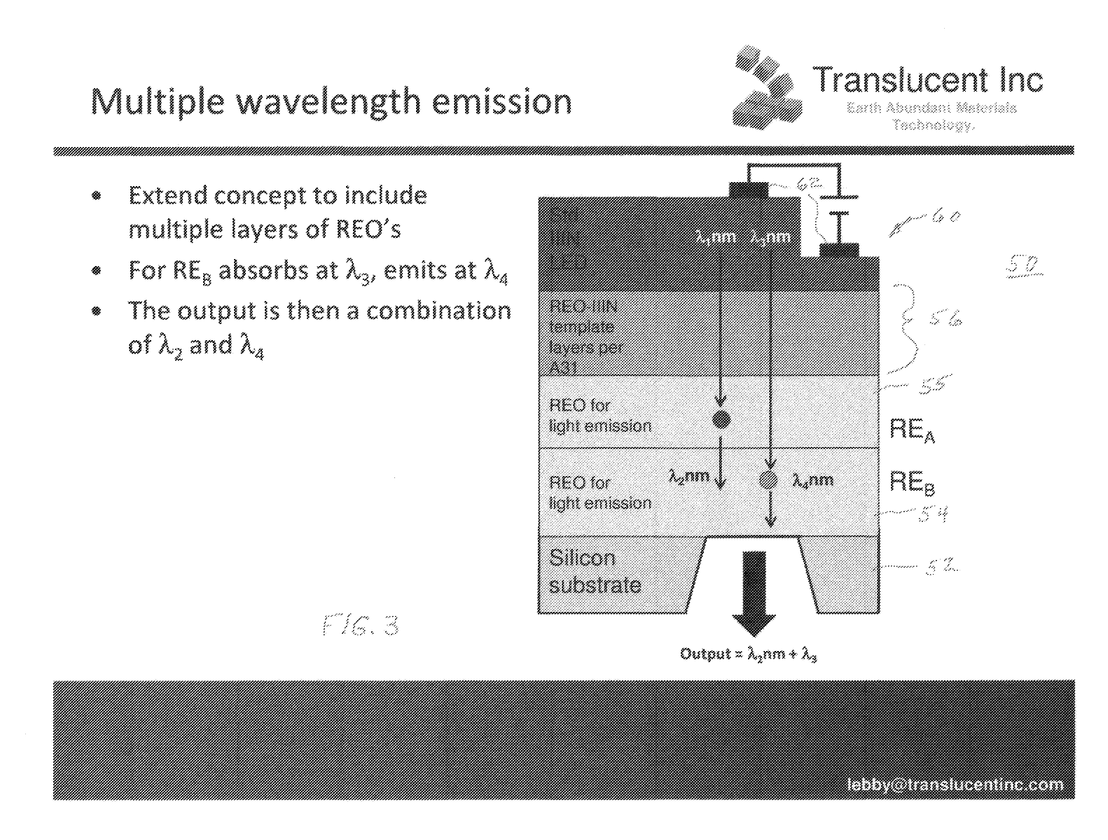

Turning now to FIG. 3, a visible light emitting diode 50 substantially incorporating a REO-Si template with integrated light emission REO layers in accordance with the present invention is illustrated. As will be understood in this example, visible light emitting diode 50 is designed for multiple wavelength light emission. Visible light emitting diode 50 includes a single crystal silicon substrate 52, a first single crystal rare earth oxide light emission layer 54, a second single crystal rare earth oxide light emission layer 55, a REO-Si template 56 generally as described above in conjunction with FIG. 1, and a III-N LED 60.

Single crystal silicon substrate 52, it will be understood, is or may be a standard well know single crystal silicon wafer or portion thereof generally known and used in the semiconductor industry. Single crystal silicon substrate 52 is not limited to any specific crystal orientation but could include <111> silicon, <110> silicon, <100> silicon or any other orientation or variation known and used in the art. Also, while silicon substrate 52 is illustrated as single crystal pure silicon it should be understood that single crystal substrates composed of materials containing elements other than silicon or in addition to silicon may be used and all such substrates will be referred to generically as “silicon” substrates herein.

First rare earth oxide light emission layer 54 is grown on silicon substrate 52 using any of the well known growth methods, such as MBE, MOCVD, PLD (pulsed laser deposition), sputtering, ALD (atomic layer deposition), or any other known growth method for thin films. Second rare earth oxide light emission layer 55 is grown on first rare earth oxide light emission layer 54 using any of the well known growth methods described above. Further, the growth method used will generally be used for all additional layers and may conveniently be employed to grow the entire structure in a continuous process sometimes referred to herein as performed within a one wafer single epitaxial process.

Light emission layers 54 and 55 are specifically selected to up-convert different emissions received from III-N LED 60 to visible light. As one example of different emissions, rare earth doped GaN has been shown to produce light at wavelengths characteristic of a rare earth dopant. Thus, the III-N layer (III-N LED 60) can be, for example, doped with more than one (multiple) dopant to provide multiple different emissions (λ₁, λ₂, λ₃ etc.). Also, LEDs in general have a broad emission spectrum and it is possible that rare earth oxides could be found to operate with many or all of the components of the emission spectrum. Further, additional layers of REO could be added to the structure of FIG. 3 so that, for example, the λ₂ and/or the λ₃ emissions could interact with other lower layers of material to produce different and/or additional output wavelengths.

In a typical example, III-N LED 60 emits at a first wavelength of λ₁ in the UV range and invisible to the human eye. Light emission layer 55 includes a rare earth specifically selected to receive λ₁, up-convert the emission to visible light at a wavelength λ₂. and emit the visible light at wavelength λ₂ downwardly through layer 54 and substrate 52. Simultaneously, III-N LED 60 emits at a second wavelength of λ₃ in the UV range and invisible to the human eye. Light emission layer 54 includes a rare earth specifically selected to receive λ₃, up-convert the emission to visible light at a wavelength λ₄. and emit the visible light at wavelength λ₄ downwardly through substrate 52. The various rare earth metals generally have 4f transition levels with the UV spectrum. Thus, to convert the multiple UV emissions from III-N LED 60 to visible light, rare earth metal oxides are selected with transition levels that correspond to the multiple emissions from III-N LED 60. In the above example the output is a combination of λ₂ and λ₄. It will be understood that layers 54 and 55 can actually be integrated into template 56 as one or more of the REO physical matching layers and may not, in fact, be a separate layer. III-N LED 60 is formed by fabricating contacts 62 on the surface of the single crystal III-N layer. In this embodiment an opening 64 is formed in the lower or backside surface of substrate 52 for the output emission from light emission layers 54 and 55.

Thus, new and improved light emitting devices including REO-Si templates with integrated REO layers for light emission have been disclosed. The new and improved III-N on silicon light emitting devices are designed to emit light in the visible range. Also, new and improved methods of fabricating III-N on silicon light emitting devices that emit light in the visible range have been disclosed. The new and improved apparatus incorporates a stress and chemical engineered epitaxial template designed to facilitate the growth of a III N nitride layer with a larger diameter and thickness. Specifically selected and designed rare earth oxide layers are integrated into or with the template to up-convert emissions from the LED into visible light.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A III-N on silicon light emitting diode constructed to emit light in the visible range comprising:
a crystalline silicon substrate having an upper surface and a lower surface;
a layer of single crystal III-N nitride with a light emitting diode formed therein and designed to emit light at a first wavelength through a lower surface;
a REO-Si template with an upper surface mated to the lower surface of the layer of single crystal III-N nitride and a lower surface designed to approximately crystal lattice match the upper surface of the silicon substrate;
a light emission layer of single crystal rare earth oxide selected to receive and absorb light at the first wavelength, up-convert the absorbed light, and re-emit light at a second wavelength in the visible range; and
the lower surface of the REO-Si template being one of mated to the upper surface of the crystalline silicon substrate with the light emission layer integrated into the REO-Si template and mated to an upper surface of the light emission layer with a lower surface of the light emission layer mated to the crystalline silicon substrate.

2. A III-N on silicon light emitting diode as claimed in claim 1 wherein the light emission layer includes a ternary alloy of rare earth oxides.

3. A III-N on silicon light emitting diode as claimed in claim 2 wherein the light emission layer includes the ternary alloy (RE₁₋ₓ, RE^{A}ₓ)₂O₃r where the RE^{A} has at least one requisite optical transition and x is in a range of >0 to <1.

4. A III-N on silicon light emitting diode as claimed in claim 3 wherein the ternary alloy includes (GdₓEr₁₋ₓ)₂O₃, where x is in a range of 0.05 to 0.25.

5. A III-N on silicon light emitting diode as claimed in claim 1 wherein the first wavelength is above 1200 nm and the second wavelength in a range of approximately 400 nm to 800 nm.

6. A III-N on silicon light emitting diode as claimed in claim 4 wherein the first wavelength is approximately 1540 nm and the second wavelength is approximately 495 nm.

7. A III-N on silicon light emitting diode as claimed in claim 4 wherein the layer of single crystal III-N nitride is designed to emit light at the first wavelength and simultaneously at a second wavelength, different than the first wavelength, through a lower surface.

8. A III-N on silicon light emitting diode as claimed in claim 7 wherein the layer of single crystal III-N nitride includes GaN doped with rare earths to emit light at the first and second wavelengths.

9. A III-N on silicon light emitting diode as claimed in claim 7 further including a second light emission layer of rare earth oxide selected to receive and absorb light at a third wavelength, up-convert the absorbed light, and re-emit light at a fourth wavelength in the visible range

10. A III-N on silicon light emitting diode as claimed in claim 9 wherein the second light emission layer is one of integrated into the REO-Si template and mated to a lower surface of the first light emission layer with a lower surface of the second light emission layer mated to the crystalline silicon substrate.

11. A III-N on silicon light emitting diode as claimed in claim 1 wherein the light emitting diode is designed to emit light at a plurality of different wavelengths through a lower surface and light emission layers of single crystal rare earth oxide selected to receive and absorb light at more than one of the different wavelengths are included.

12. A III-N on silicon light emitting diode constructed to emit light in the visible range comprising:
a crystalline silicon substrate having an upper surface and a lower surface;
a layer of single crystal III-N nitride with a light emitting diode formed therein and designed to emit light at a first wavelength through a lower surface;
a REO-Si template with an upper surface mated to the lower surface of the layer of single crystal III-N nitride and a lower surface designed to approximately crystal lattice match the upper surface of the silicon substrate; and
a light emission layer of rare earth oxide selected to receive and absorb light at the first wavelength, up-convert the absorbed light, and re-emit light at a second wavelength in the visible range, and a lower surface of the light emission layer being mated to the upper surface of the crystalline silicon substrate and the upper surface of the light emission layer being mated to the lower surface of the REO-Si template.

13. A III-N on silicon light emitting diode as claimed in claim 12 wherein the light emission layer includes a ternary alloy of rare earth oxides.

14. A III-N on silicon light emitting diode as claimed in claim 13 wherein the light emission layer includes the ternary alloy (RE₁₋ₓ, RE^{A}ₓ)₂O₃, where the RE^{A} has requisite optical transitions and x is in a range of >0 to <1.

15. A method of fabricating a III-N on silicon light emitting diode constructed to emit light in the visible range comprising the steps of and not necessarily in the order listed:
providing a crystalline silicon substrate having an upper surface and a lower surface;
epitaxially growing a layer of single crystal III-N nitride with a light emitting diode formed therein and designed to emit light at a first wavelength through a lower surface;
epitaxially growing a REO-Si template with an upper surface mated to the lower surface of the layer of single crystal III-N nitride and a lower surface designed to approximately crystal lattice match the upper surface of the silicon substrate;
epitaxially growing a light emission layer of single crystal rare earth oxide selected to receive and absorb light at the first wavelength, up-convert the absorbed light, and re-emit light at a second wavelength in the visible range; and
mating the lower surface of the REO-Si template to one of the upper surface of the crystalline silicon substrate with the light emission layer integrated into the REO-Si template or to an upper surface of the light emission layer with a lower surface of the light emission layer mated to the crystalline silicon substrate.

16. A method as claimed in claim 15 wherein the step of epitaxially growing the light emission layer includes epitaxially growing a ternary alloy of rare earth oxides.

17. A method as claimed in claim 16 wherein the step of epitaxially growing the light emission layer includes growing the ternary alloy (RE₁₋ₓ RE^{A}ₓ)₂O₃, where the RE^{A} has requisite optical transitions and x is in a range of >0 to <1.

18. A method as claimed in claim 15 further including a step of epitaxially growing a second light emission layer of single crystal rare earth oxide and selecting the second light emission layer to receive and absorb light at a third wavelength, up-convert the absorbed light, and re-emit light at a fourth wavelength in the visible range, wherein the second light emission layer is one of integrated into the REO-Si template and mated to a lower surface of the first light emission layer with a lower surface of the second light emission layer mated to the crystalline silicon substrate.

19. A method of fabricating a III-N on silicon light emitting diode constructed to emit light in the visible range comprising the steps of:
providing a crystalline silicon substrate having an upper surface and a lower surface;
epitaxially growing a light emission layer of single crystal rare earth oxide on the upper surface of the crystalline silicon substrate, and selecting the light emission layer to receive and absorb light at a first wavelength, up-convert the absorbed light, and re-emit light at a second wavelength in the visible range;
epitaxially growing a REO-Si template on the light emission layer with a lower surface mated to an upper surface of the light emission layer; and
epitaxially growing a layer of single crystal III-N nitride on an upper surface of the REO-Si template, designing the layer of single crystal III-N nitride to emit light at the first wavelength through a lower surface, and forming a light emitting diode in/on the layer of single crystal III-N nitride.

20. A method as claimed in claim 19 wherein the step of epitaxially growing the light emission layer includes epitaxially growing a ternary alloy of rare earth oxides.

21. A method as claimed in claim 20 wherein the step of epitaxially growing the light emission layer includes growing the ternary alloy (RE₁₋ₓ RE^{A}ₓ)₂O₃, where the RE^{A} has requisite optical transitions and x is in a range of >0 to <1.
